(19) United States
(12) Patent Application Publication
(10) Pub. No.: US 2024/0429306 A1
(43) Pub. Date: Dec. 26, 2024

(54) SEMICONDUCTOR HETEROSTRUCTURES WITH QUATERNARY III-NITRIDE ALLOY

(71) Applicant: The Regents of the University of Michigan, Ann Arbor, MI (US)

(72) Inventors: Zetian Mi, Ann Arbor, MI (US); Ping Wang, Ann Arbor, MI (US); Ding Wang, Ann Arbor, MI (US)

(21) Appl. No.: 18/703,492

(22) PCT Filed: Oct. 24, 2022
(86) PCT No.: PCT/US2022/047555

§ 371 Date: Apr. 22, 2024

Related U.S. Application Data
(60) Provisional application No. 63/270,693, filed on Oct. 22, 2021.

(51) Int. Cl. H01L 29/66; H01L 21/02; H01L 29/20; H01L 29/778

(52) U.S. Cl. CPC H01L 29/66462; H01L 21/02458; H01L 21/02502; H01L 21/0254; H01L 29/2003; H01L 29/7786

(57) ABSTRACT

A method includes of fabricating a heterostructure includes growing epitaxially, in a growth chamber, a first semiconductor layer of the heterostructure, the first semiconductor layer comprising a III-nitride semiconductor material, the first semiconductor layer being supported by a substrate, and, after growing the first semiconductor layer, growing epitaxially, in the growth chamber, a second semiconductor layer of the heterostructure such that the second semiconductor layer is supported by the first semiconductor layer, the second semiconductor layer comprising a quaternary or higher order III-nitride alloy. The quaternary or higher order III-nitride alloy comprises a group IIIB element

### CROSS-REFERENCE TO RELATED APPLICATION

This application claims the benefit of U.S. provisional application entitled “Semiconductor Heterostructures with Quaternary III-Nitride Alloy,” filed Oct. 22, 2021, and assigned Ser. No. 63/270,693, the entire disclosure of which is hereby expressly incorporated by reference.

### STATEMENT REGARDING FEDERALLY SPONSORED RESEARCH OR DEVELOPMENT

This invention was made with government support under Contract No. N00014-19-1-2225 awarded by the Naval Research Office. The government has certain rights in the invention.

### BACKGROUND OF THE DISCLOSURE

### Field of the Disclosure

The disclosure relates generally to III-nitride semiconductor heterostructures.

### Brief Description of Related Technology

ScAlN is an emerging ultrawide bandgap semiconductor for next-generation radio-frequency electronic and other devices. To date, however, it has remained challenging to achieve high quality ScAlN.

The GaN-based photonics and electronics eco-system has been significantly expanded by incorporating transition metal elements, such as Sc, Y, and Nb, which offers new functionalities, for instance, ferroelectricity and superconductivity. In particular, wurtzite ScₓAl₁₋ₓN with tunable bandgap has attracted interest due to its unique ferroelectricity, enhanced piezoelectric response, and large spontaneous polarization, which have shown promising applications in micro-/nano-electromechanical systems, high electron mobility transistors (HEMTs), and memory devices towards neuromorphic computing and artificial intelligence. High material quality, e.g., pure crystal phase, a low level of dislocation/defect/impurity density, and sharp interface, is useful in realizing those promising applications. Early studies have been focused mostly on the use of sputter deposition. Recently, state-of-the-art epitaxy approaches for nitride semiconductors, e.g., molecular beam epitaxy (MBE) and metal-organic vapor deposition (MOCVD), have also been successfully employed for the epitaxial growth of ScₓAl₁₋ₓN, enabling seamless integration of Sc-III-N functional structures with traditional GaN-based device technology.

Due to the lack of an efficient precursor for Sc during MOCVD processes, research on epitaxial ScₓAl₁₋ₓN has been conducted using MBE. In the past few years, efforts have been devoted to improving the phase purity, crystal quality, and morphology of ScₓAl₁₋ₓN grown by MBE but with very limited success. To date, the epitaxy techniques have been largely focused on the N-rich growth regime to avoid undesirable intermetallic Sc—Al and perovskite Sc₃AlN formation. Consequently, the dominant three-dimensional (3D) growth mode caused by N-rich conditions resulted in a granular surface for ScₓAl₁₋ₓN, instead of the atomic steps achieved for conventional III-nitride epilayers. Localized trap states will generate at such granular interface regions, which limit the transport properties of mobile carriers, resulting in degenerated device performance.

### SUMMARY OF THE DISCLOSURE

In accordance with one aspect of the disclosure, method of fabricating a heterostructure includes growing epitaxially, in a growth chamber, a first semiconductor layer of the heterostructure, the first semiconductor layer including a III-nitride semiconductor material, the first semiconductor layer being supported by a substrate, and after growing the first semiconductor layer, growing epitaxially, in the growth chamber, a second semiconductor layer of the heterostructure such that the second semiconductor layer is supported by the first semiconductor layer, the second semiconductor layer including a quaternary or higher order III-nitride alloy. The quaternary or higher order III-nitride alloy includes a group IIIB element.

In accordance with another aspect of the disclosure, a method of fabricating a heterostructure includes growing epitaxially a first semiconductor layer of the heterostructure, the first semiconductor layer including a III-nitride semiconductor material, the first semiconductor layer being supported by a substrate, and, after growing the first semiconductor layer, growing epitaxially a second semiconductor layer of the heterostructure such that the second semiconductor layer is supported by the first semiconductor layer, the second semiconductor layer including a quaternary or higher order III-nitride alloy. The quaternary or higher order III-nitride alloy includes a group IIIB element. Growing the second semiconductor layer is implemented in a metal-rich environment.

In accordance with yet another aspect of the disclosure, a device includes a substrate and a semiconductor heterostructure supported by the substrate. The semiconductor heterostructure includes a first semiconductor layer supported by the substrate and including a III-nitride semiconductor material, and a second semiconductor layer supported by the first semiconductor layer and including a quaternary or higher order III-nitride alloy, the quaternary or higher order III-nitride alloy including a group IIIB element. The second semiconductor layer has a terraced surface distal to the first semiconductor layer.

In accordance with still yet another aspect of the disclosure, a device includes a substrate, and a semiconductor heterostructure supported by the substrate. The semiconductor heterostructure includes a first semiconductor layer supported by the substrate and including a III-nitride semiconductor material, and a second semiconductor layer supported by the first semiconductor layer and including a quaternary or higher order III-nitride alloy, the quaternary or higher order III-nitride alloy including a group IIIB element. A composition of the group IIIB element falls in a range from about 0.10 to about 0.50.

In accordance with still another aspect of the disclosure, a device includes a substrate, a buffer layer supported by the substrate and including a III-nitride semiconductor material, and a barrier layer supported by the buffer layer and including a quaternary or higher order III-nitride alloy, the quaternary or higher order III-nitride alloy including a group IIIB element. The barrier layer has a terraced surface distal to the buffer layer.

In connection with any one of the aforementioned aspects, the devices and/or methods described herein may alternatively or additionally include or involve any combination of one or more of the following aspects or features. Growing epitaxially the second semiconductor layer is implemented in a metal-rich environment. Growing epitaxially the second semiconductor layer is implemented in a gallium-rich or indium-rich environment. Growing the second semiconductor layer is implemented without removal of the substrate from the growth chamber after growth of the first semiconductor layer. Growing epitaxially the second semiconductor layer includes adjusting a IIIB element/metal flux ratio during epitaxial growth of the second semiconductor layer. The IIIB element/metal flux ratio is a scandium/aluminum flux ratio. Growing epitaxially the second semiconductor layer is implemented with a flux ratio such that a composition of the group IIIB element falls in a range from about 0.10 to about 0.50. The group IIIB element is a lanthanide element. The metal-rich environment is a gallium-rich or indium-rich environment. Growing the first semiconductor layer and growing the second semiconductor layer are implemented without removal of the substrate from a growth chamber in which the first and second semiconductor layers are grown. Growing epitaxially the second semiconductor layer includes adjusting a IIIB element/metal flux ratio during epitaxial growth of the second semiconductor layer. The IIIB element/metal flux ratio is a scandium/aluminum flux ratio. The terraced surface includes a plurality of atomic steps. A composition of the group IIIB element falls in a range from about 0.10 to about 0.50. The second semiconductor layer is in contact with the first semiconductor layer. The device further includes a third semiconductor layer disposed between the first and second semiconductor layers. The third semiconductor layer includes a further III-nitride semiconductor material differing from the III-nitride semiconductor material of the first semiconductor layer. The first and second semiconductor layers are lattice matched. The first and second semiconductor layers are lattice mismatched. The second semiconductor layer is configured as a dielectric layer. The transistor device further includes a channel layer supported by the barrier layer and including a compound semiconductor material, in which the terraced surface is proximate to the channel layer. The transistor device further includes a channel layer disposed between the buffer layer and the barrier layer and including a compound semiconductor material, in which the terraced surface is distal to the channel layer. The compound semiconductor material and the quaternary or higher order III-nitride alloy are lattice mismatched. The compound semiconductor material and the quaternary or higher order III-nitride alloy are lattice matched. The III-nitride semiconductor material and the quaternary or higher order III-nitride alloy are lattice mismatched. The transistor device further includes a further semiconductor layer disposed between the buffer and barrier layers, in which the further semiconductor layer includes a further III-nitride semiconductor material differing from the III-nitride semiconductor material of the first semiconductor layer.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts atomic force microscope (AFM) images of quaternary III-nitride semiconductor layers (e.g., ScₓAl_{y}Ga_{1-x-y}N layers) of heterostructures in accordance with a number of examples, along with AFM images of ScₓAl₁₋ₓN layers for purposes of comparison.

FIG. 2 depicts graphical plots of x-ray diffraction (XRD) data for the samples and examples shown in FIG. 1.

FIG. 3 depicts a cross-sectional high-angle annular dark field scanning transmission electron microscope (HAADF-STEM) image of a ScₓAl_{y}Ga_{1-x-y}N/GaN multilayer stack or heterostructure in accordance with one example, as well as graphical plots of corresponding energy dispersive x-ray spectroscopy (EDS) maps for the multilayer stack, nanobeam diffraction patterns acquired from the multilayer stack, and HAADF-STEM images of various heterointerface regions of the multilayer stack.

FIG. 4 depicts graphical plots of atomic content and impurity concentration in a ScₓAl_{y}Ga_{1-x-y}N/GaN multilayer stack in accordance with one example.

FIG. 5 depicts AFM images of superlattice (SL) heterostructures in accordance with two examples, as well as a graphical plot of XRD scan data for the SL heterostructures and a schematic, cross-sectional view of the ScₓAl_{y}Ga_{1-x-y}N/GaN SL heterostructure.

FIG. 6 is a flow diagram of a method of fabricating a heterostructure with a quaternary III-nitride semiconductor layer in accordance with one example.

FIG. 7 depicts schematic views of transistor devices having a semiconductor heterostructure with a quaternary or higher order III-nitride semiconductor layer in accordance with two examples.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Transistor and other devices with heterostructures having a quaternary or higher order III-nitride semiconductor layer are described. As described herein, the quaternary or higher order III-nitride semiconductor layer allows a higher material quality to be achieved relative to other III-nitride alloys, such as ScAlN. In some cases, the quaternary or higher order III-nitride semiconductor layer involves alloying ScAlN with Ga. The disclosed heterostructures provide a useful approach for achieving high quality Sc-III-N semiconductors that was not previously possible, and further offers additional dimensions for bandgap, polarization, interface, strain, and quantum engineering. The resulting quaternary alloy ScAlGaN exhibits single-phase wurtzite structure, an atomically smooth surface, high crystal quality, a sharp interface, and low impurity concentration. Moreover, oxygen impurity incorporation in the ScAlGaN examples is found to be three to four orders of magnitude lower, compared to that of ScAlN templates utilizing a similar Sc source. Methods for fabricating such devices through epitaxial growth of the quaternary or higher order III-nitride semiconductor layer are also described. For instance, molecular beam epitaxy (MBE) may be used.

In one aspect, the challenges presented by previous attempts to grow high quality ScₓAl₁₋ₓN layers are addressed by use of a metal-rich growth regime. For instance, the metal-rich growth regime may include incorporating Ga, i.e., forming quaternary alloy ScₓAl_{y}Ga_{1-x-y}N, during the epitaxy process. In this growth regime, the migration ability of impinging atoms can be significantly enhanced. ScₓAl_{y}Ga_{1-x-y}N and other quaternary III-nitride semiconductors can also provide additional dimensions or options to tune the lattice parameters, strain, band structures, polarization, and ferroelectric characteristics.

In some cases, the devices are configured as HEMT devices, such as GaN HEMT devices. For instance, described herein are examples of ScAlGaN/GaN superlattices or heterostructures that exhibit clear periodicity with sharp interfaces. GaN high electron mobility transistors with high sheet electron density and high mobility are realized using ScAlGaN as barrier. Using a quaternary or higher order III-nitride semiconductor layer as the barrier in GaN HEMT devices may be useful in improving the operating frequency while maintaining high output power.

In some cases, the quaternary or higher order III-nitride semiconductor layer is configured, or functions, as a dielectric layer for electronic devices including, for instance, high electron mobility transistors. Such dielectric layers may be useful in a wide variety of electronic devices.

Described herein are examples of the growth of quaternary or higher order alloys, such as ScₓAl_{y}Ga_{1-x-y}N with varying Sc contents or composition levels (e.g., x of about 0.16 to about 26) by introducing Ga during the epitaxy of ScₓAl₁₋ₓN using plasma-assisted MBE. Growth parameters, surface morphology, crystal quality, structural properties, and impurity incorporation of ScₓAl_{y}Ga_{1-x-y}N have been investigated in detail. Atomically smooth surfaces, improved crystal quality, sharp interfaces, and low impurity concentration unambiguously support that the material quality of ScₓAl_{y}Ga_{1-x-y}N is drastically improved compared to ScₓAl₁₋ₓN. The presence of clear periodicity for ScₓAl_{y}Ga_{1-x-y}N/GaN superlattices, together with the demonstration of high electron sheet density and high carrier mobility of HEMTs, further suggest that ScₓAl_{y}Ga_{1-x-y}N possesses significant advantages over or beyond ScₓAl₁₋ₓN in optoelectronic, electronic, and other applications.

Although described in connection with HEMT devices, the disclosed methods and devices may be applied to a wide variety of electronic and other devices. For instance, the disclosed devices may be non-electronic devices, such as photonic, acoustic, and piezoelectric devices.

Although described in connection with examples having a ScₓAl_{y}Ga_{1-x-y}N layer, the disclosed methods and devices are also useful in connection with other scandium III-nitride semiconductor alloy materials. For instance, III-nitride semiconductor alloy materials, such as ScₓAl_{y}In_{1-x-y}N and ScₓGa_{y}In_{1-x-y}N may be used. Still other III-nitride semiconductor alloy materials may be used. For instance, the semiconductor layer may be composed of another quaternary or higher order III-nitride alloy, including, for instance, a pentanary III-nitride alloy, such as ScAlGaInN.

The configuration, construction, fabrication, and other characteristics of the heterostructures may also vary from the examples described. For instance, the heterostructures may include any number of epitaxially grown layers of ferroelectric and non-ferroelectric nature. The disclosed methods and devices are not limited to gallium nitride alloys including scandium. For instance, the III-nitride alloys may include additional or alternative group IIIB elements, such as yttrium (Y) and lanthanum (La), and other rare earth elements, such as any of the other 14 lanthanides Ce—Lu. The term “group IIIB element” is accordingly used herein in a manner that includes the lanthanides, such that the terms “group IIIB element” and “rare earth element” may be used interchangeably.

The heterostructures of the disclosed devices may include any number of other alloys of III-nitride materials, including, for instance, ScₓAl_{1-x-y}N layers (e.g., single-crystalline ScₓAl₁₋ₓN). Such ScₓAl₁₋ₓN layers may also be grown by plasma-assisted MBE and exhibit robust ferroelectric switching. Further details regarding such layers are set forth in U.S. Application Ser. No. 63/185,669, entitled “Epitaxial Nitride Ferroelectronics” and filed May 7, 2021, and P. Wang, et al., “Fully epitaxial ferroelectric ScAlN grown by molecular beam epitaxy,” Applied Physics Letters 118, 223504 (2021), the entire disclosures of which are hereby incorporated by reference.

Although described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

The examples of ScₓAl_{y}Ga_{1-x-y}N films described herein were grown by a Veeco GENxplor MBE system, in which active nitrogen atoms (N*) were provided using a radio-frequency (RF) plasma source, while Sc, Al, and Ga were evaporated from Knudsen cells.

ScₓAl_{y}Ga_{1-x-y}N films with thicknesses of about 100 to about 120 nm were grown on commercial GaN templates. A 100-nm-thick GaN buffer was deposited before the growth of ScₓAl_{y}Ga_{1-x-y}N. A nitrogen (N₂) flow rate of 0.3 sccm with an RF forward power of 350 W was used throughout the growth. The Sc content was controlled by tuning the Sc/Al flux ratio, and the corresponding (Sc+Al)/N* flux ratio varies from about 0.87 to about 0.85 with increasing Sc flux. The beam equivalent pressure (BEP) for Sc, Al, and Ga is listed in detail in Table I below. All samples were grown at about 700° C., which was monitored by a thermocouple placed at the backside of the substrate. Other growth temperatures may be used in other examples (e.g., examples involving other quaternary or higher order III-nitride semiconductor layers), including, for instance, temperatures falling in a range from about 400° C. to about 1000° C.

Reflection high energy electron diffraction (RHEED) was used to in situ monitor the whole growth process. The surface morphology was characterized using an ICON atomic force microscope (AFM). X-ray diffraction (XRD) was carried out using a Rigaku SmartLab and Bruker D8 diffractometers with a Cu K_{α1} radiation X-ray source (1.5406 Å). Sc contents were determined utilizing energy dispersive x-ray spectroscopy (EDS) equipped on a Hitachi SU8000 scanning electron microscope (SEM) and a TF Talos F200X scanning transmission electron microscope (STEM, 200 keV, 10.5 mrad semi-convergence angle) with 125 mm camera length and 0.9 srad solid angle. High-angle annular dark field STEM (HAADF-STEM) images were collected using a Cs aberration corrected JEOL 3100R05 microscope (300 keV, 22 mrad) and a 120 mm camera length. Secondary-ion mass spectrometry (SIMS) profiling was also carried out.

As shown in Table I herein, three series of example layers or heterostructures were grown to explore the epitaxy behaviors and characteristics of ScₓAl_{y}Ga_{1-x-y}N: (i) ScₓAl_{1-x-y}N layers grown with varying Sc contents deposited under conventional N-rich growth conditions as control layers (S1, S5, and S6), (ii) ScₓAl_{y}Ga_{1-x-y}N layers grown with varying Ga fluxes while maintaining the Sc and Al flux constant (S2, S3, and S4), and (iii) ScₓAl_{y}Ga_{1-x-y}N layers grown with varying Sc/Al flux ratios while maintaining the Ga flux constant (S3, S7, and S8). Examples S3, S4, S7, and S8 were grown in a metal-rich environment, e.g., under Ga-rich conditions, which was evidenced by the presence of Ga droplets on the as-grown surface. The Sc contents acquired by SEM-EDS from a single ScₓAl_{y}Ga_{1-x-y}N layer grown on GaN and AlN templates and the Sc contents measured by STEM-EDS from a ScₓAl_{y}Ga_{1-x-y}N/GaN multilayer stack sample are listed in Table I as normal and underlined values, respectively. The relative Sc content is defined as the atomic percent in ScₓAl_{y}N, i.e., x/(x+y).

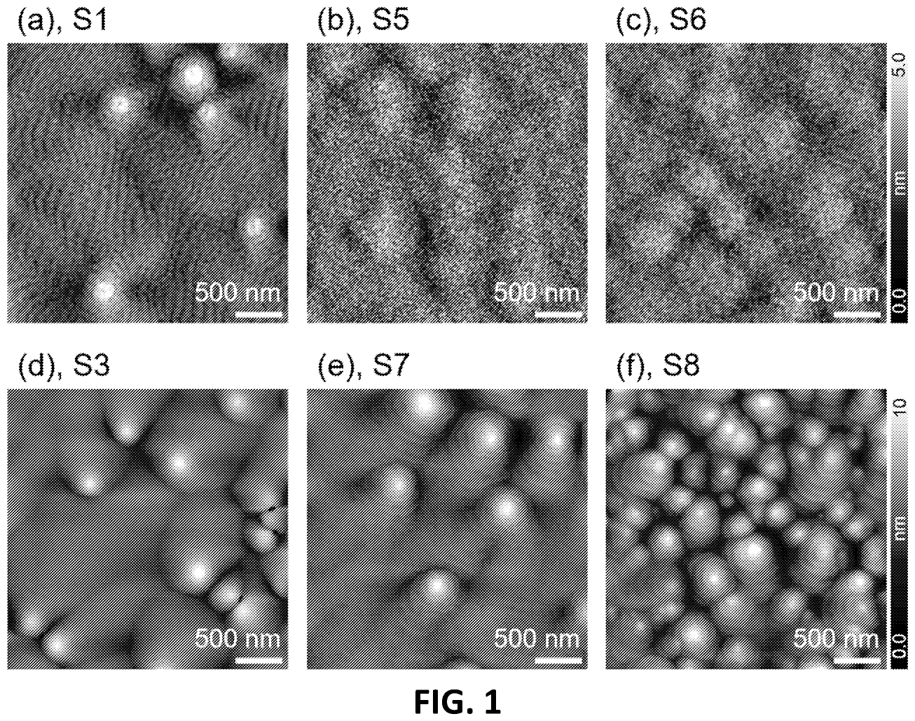

In Parts A-C, FIG. 1 depicts 3×3 μm² AFM images of ScₓAl₁₋ₓN layers with varying Sc contents: (A) x=0.18 (Sample S1 of Table I), (B) x=0.28 (Sample S5), and (C) x=0.36 (Sample S6). Parts D-F of FIG. 1 depict AFM images of examples of ScₓAl_{y}Ga_{1-x-y}N layers with varying Sc contents as follows: (D) x=0.16, y=0.77 (Example S3), (E) x=0.21, y=0.68 (Example S7), and (F) x=0.26, y=0.60 (Example S8). The height color scale range is 5 nm for Parts A-C and 10 nm for Parts D-F.

TABLE I
Growth parameters [Sc/Al/Ga BEP and (Sc + Al)/N* flux ratio],
Sc (x), Al (y), Ga (1 − x − y), and relative Sc* [x / (x + y)]
contents measured by SEM-EDS (normal values) and
STEM-EDS (underlined values), and surface RMS
roughness (R_{q}, acquired from a 3 × 3 μm² scan area)
of ScₓAl_{y}Ga_{1-x-y}N films.

| | BEP | | | | Atomic content in ScₓAl_{y}Ga_{1-x-y}N | | | | |
|---|---|---|---|---|---|---|---|---|---|
| | (10⁻⁸ Torr) | | | | Sc | Al | Ga | Sc* | R_{q} |
| Sample | Sc | Al | Ga | (Sc + Al)/N* | (x) | (y) | (1 − x − y) | [x / (x + y)] | (nm) |
| S1 | 1.6 | 6.4 | — | 0.87 | 0.18 | 0.82 | — | 0.18 | 0.49 |
| S2 | 1.6 | 6.4 | 3.0 | 0.87 | 0.16 | 0.77 | 0.07 | 0.17 | 1.58 |
| S3 | 1.6 | 6.4 | 5.0 | 0.87 | 0.16 | 0.77 | 0.07 | 0.17 | 1.31 |
| S4 | 1.6 | 6.4 | 10 | 0.87 | 0.16 | 0.77 | 0.07 | 0.17 | 1.16 |
| S5 | 2.4 | 5.6 | — | 0.86 | 0.28 | 0.72 | — | 0.28 | 0.61 |
| S6 | 3.2 | 4.8 | — | 0.85 | 0.36 | 0.64 | — | 0.36 | 0.63 |
| S7 | 2.4 | 5.6 | 5.0 | 0.86 | 0.21 | 0.68 | 0.11 | 0.24 | 0.86 |
| S8 | 3.2 | 4.8 | 5.0 | 0.85 | 0.26 | 0.60 | 0.14 | 0.30 | 1.29 |

The effect of Ga incorporation was evaluated by varying the Ga flux during the growth of Sc_{0.18}Al_{0.82}N. With Ga incorporation, the segmented RHEED patterns gradually evolved into narrow streaky patterns, indicating improved surface morphology. Shown in Part A of FIG. 1, Sc_{0.18}Al_{0.82}N grown under N-rich conditions has a granular surface, suggesting limited migration length of adatoms. However, atomically smooth regions started to appear on the surface after introducing a small amount of Ga [3.0×10⁻⁸ Torr, Example S2]. Shown in Part D of FIG. 1, with further increasing Ga flux (5.0×10⁻⁸ Torr, Example S3), atomic steps are readily observed over the full wafer. The surface exhibits no observable changes with introducing more Ga [1.0×10⁻⁷ Torr, Example S4]. These phenomena indicate that the migration ability of adatoms is significantly enhanced by introducing Ga during the growth of ScₓAl₁₋ₓN. Consequently, clear spiral atomic steps formed around the hillocks. STEM-EDS and SIMS measurements confirmed that Ga was indeed incorporated into the ScₓAl₁₋ₓN lattice, forming the quaternary alloy ScₓAl_{y}Ga_{1-x-y}N. Herein Sc_{0.16}Al_{0.77}Ga_{0.07}N was formed instead of Sc_{0.18}Al_{0.82}N after incorporating Ga (see Table I). Importantly, the wurtzite crystal structure is well maintained, except for the (0002) diffraction peak exhibiting a small shift towards the lower angle side, indicating an increased out-of-plane lattice parameter. The quaternary alloy layer thus exhibits a wurtzite crystal structure. To avoid excessive Ga accumulation, an optimized Ga BEP of 5.0×10⁻⁸ Torr was employed to investigate the extensibility of this growth strategy on ScₓAl₁₋ₓN with higher Sc contents, but the Ga (or other metal) beam equivalent pressures may vary in other cases.

ScₓAl₁₋ₓN samples with varying Sc contents (x˜0.18-0.36) were grown under N-rich conditions for comparison. Parts A-C of FIG. 1 illustrate the corresponding 3×3 μm² AFM images. The AFM images exhibit granular surfaces.

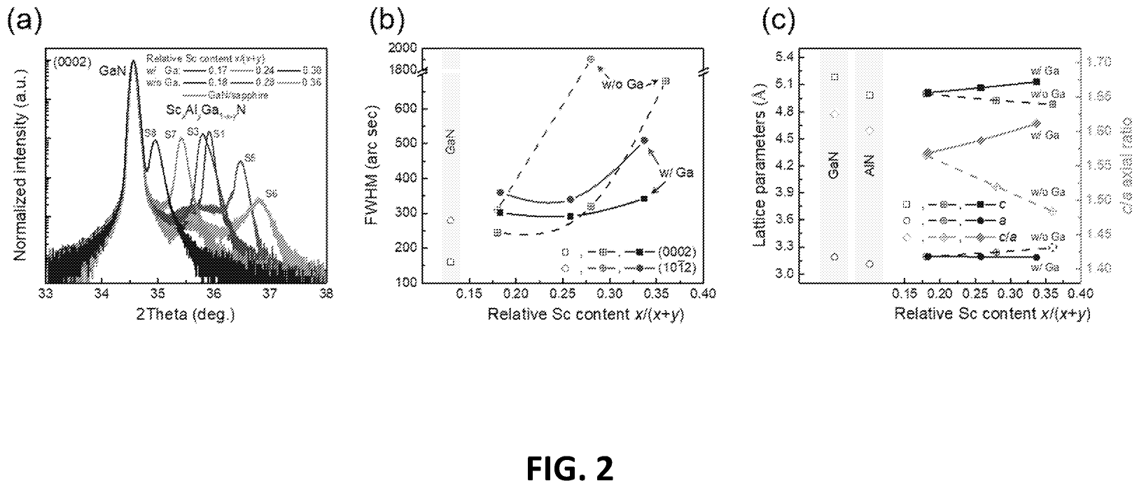

Interestingly, with Ga incorporation, all RHEED patterns transformed to narrow streaky lines, and Kikuchi lines were seen clearly, indicating a high crystalline quality and smooth surface. Parts D-F of FIG. 1 show the surface morphology of example ScₓAl_{y}Ga_{1-x-y}N films, exhibiting clear spiral atomic steps instead of nanograins. Meanwhile, the hillocks associated with threading dislocations become more observable in the ScₓAl_{y}Ga_{1-x-y}N examples compared to the ScₓAl₁₋ₓN samples. The high density of hillocks indicates a high dislocation density for sample S8, which was confirmed by XRD measurements (see, e.g., FIG. 2). The average terrace width measured near the center of the hillocks for examples S3, S7, and S8 is about 20±5, 40±5, and 60±5 nm, respectively, suggesting the increase of diffusion length for adatoms. This is mainly due to the simultaneous increase of Ga incorporation with increasing Sc content (see, e.g., Table I). The dramatic improvement of surface morphologies indicates that Ga can be used to address the poor surfaces arising from N-rich growth conditions, and to also act as a surfactant to enhance the migration ability of adatoms.

As shown in Table I, the content of Ga increases gradually with increasing Sc content (examples S3, S7 and S8). Considering Sc and Al have larger bonding energies with N atoms relative to Ga, Ga can only bond with the excess active N atoms after all Sc and Al atoms are incorporated. In this context, the following two reasons may be responsible for the increase of Ga content with increasing Sc content. Firstly, the (Sc+Al)/N* flux ratio gradually reduces from 0.87 to 0.85 with increasing Sc content in the growth strategy (see, e.g., Table I). Therefore, more Ga atoms can be incorporated into the ScₓAl₁₋ₓN with higher Sc content when grown under Ga-rich conditions. Secondly, the effective N* flux is increased due to the catalytic decomposition of N₂ induced by the presence of Sc, and the additional N* flux is proportional to the Sc flux. Therefore, some of the non-activated N₂ molecules and the N₂ molecules formed from the desorbed active N* atoms can be further decomposed into active N* atoms, which, in turn, participate in the growth. In this case, ScₓAl_{1-x-y}N with higher Sc content promotes more Ga atom incorporation due to the more additional N* flux.

FIG. 2 depicts in part A (0002) plane XRD 2θ-ω scans for the ScₓAl₁₋ₓN samples (orange, pink, and violet curves) and the ScₓAl_{y}Ga_{1-x-y}N examples (red, green, and blue curves) shown in FIG. 1. Part B of FIG. 2 depicts XRD rocking curve (XRC) full width at half maximum (FWHM) data for the (0002) plane (blue curves) and (1012) plane (red curves) for the ScₓAl_{1-x-y}N samples (dashed curves) and the ScₓAl_{y}Ga_{1-x-y}N examples (solid curves). Part C of FIG. 2 presents lattice parameter data (blue curves) and c/a ratio data (green curves) for the ScₓAl₁₋ₓN samples (dashed curves) and the ScₓAl_{y}Ga_{1-x-y}N examples (solid curves). Further details regarding the data presented in FIG. 2 are provided below.

Part A of FIG. 2 presents the XRD 2θ-ω scans for the samples and examples shown in FIG. 1. All samples and examples exhibit a characteristic diffraction peak for wurtzite structure. No other phase from ScₓAl_{y}Ga_{1-x-y}N was observed in a long-range scan (20=30-100°). The diffraction peak of ScₓAl₁₋ₓN gradually shifts towards the higher angle side with increasing Sc content (orange, pink, and violet curves). Peak widening as well as weakening is observable for higher Sc contents. The broad peak at about 35.5° originates from a sputter deposited AlN buffer that was used for the GaN template growth. Unexpectedly, with the incorporation of Ga, the diffraction peak of ScₓAl_{y}Ga_{1-x-y}N shifts to a completely opposite direction, i.e., towards the GaN (0002) peak, even when both the Sc content and relative Sc content keep increasing (red, green, and blue curves). No obvious degeneration of ScₓAl_{y}Ga_{1-x-y}N (0002) peak was seen with increasing Sc content, which is in contrast to the generally observed diminishing of diffraction peak in ScₓAl₁₋ₓN with high Sc contents.

Part B of FIG. 2 displays the FWHM of the (0002) and (101̅2) planes XRD rocking curves (XRC) of ScₓAl_{y}Ga_{1-x-y}N films. The increase of FWHM for both (0002) and (101̅2) planes XRC with increasing Sc content is a common issue for ScₓAl₁₋ₓN. Due to the severe degradation of material quality in ScₓAl₁₋ₓN, the (101̅2) plane XRC for Sc_{0.36}Al_{0.64}N is unmeasurable. The (0002) plane XRC of ScₓAl_{y}Ga_{1-x-y}N exhibits a similar increasing trend (blue solid curve), however, the FWHM varies within 50 arc sec, which is much lower than that for ScₓAl₁₋ₓN (about 150 arc sec). The FWHM of the ScₓAl_{y}Ga_{1-x-y}N (1012) plane XRC also shows a similar increasing trend with the increase of Sc content (red solid curve). However, with the same Sc content level, the (101̅2) plane FWHM of the ScₓAl_{y}Ga_{1-x-y}N layer is significantly smaller than the ScₓAl₁₋ₓN samples, indicating a dramatic suppression of the edge dislocations in the ScₓAl_{y}Ga_{1-x-y}N films.

The deduced in-plane (a) and out-of-plane (c) lattice parameters for ScₓAl_{y}Ga_{1-x-y}N are shown in Part C of FIG. 2. The corresponding values for GaN and AlN are also plotted for comparison. The evolution trend of the lattice parameters c, a, and their ratio c/a for ScₓAl₁₋ₓN (dashed curves) are consistent with previous theoretical calculation and experimental reports. Apparently, the out-of-plane lattice parameter c increases linearly with increasing relative Sc content of ScₓAl_{y}Ga_{1-x-y}N, while the in-plane lattice parameter a almost shares a similar value as GaN, indicating a coherent growth for all of the ScₓAl_{y}Ga_{1-x-y}N examples on GaN templates. Consequently, the c/a ratio exhibits an increasing trend for ScₓAl_{y}Ga_{1-x-y}N. Based on theoretical calculations, both ScₓAl₁₋ₓN (x>0.20) and ScₓGa₁₋ₓN grown on GaN suffer from a strong in-plane biaxial compressive strain. For ScₓAl₁₋ₓN, the granular morphology caused by the 3D growth mode under N-rich conditions can efficiently release the strain. However, the improved 2D epitaxial growth of ScₓAl_{y}Ga_{1-x-y}N under metal-rich conditions maintains the strain caused by lattice mismatch, i.e., ScₓAl_{y}Ga_{1-x-y}N grown on GaN suffers a strong compressive strain, which is likely the reason for the obvious shift of diffraction peaks towards GaN.

The presence or amount of lattice strain in the quaternary or higher order alloy layers (e.g., ScₓAl_{y}Ga_{1-x-y}N layers) of the disclosed heterostructures may be tuned by adjusting the composition levels of the alloy. For example, in ScₓAl_{y}Ga_{1-x-y}N examples, the Sc and/or the Ga composition levels may be tuned or otherwise adjusted separately. Such tuning may be used to achieve a desired composition level throughout the quaternary alloy layer to establish an amount of lattice matching or mismatching with adjacent layers in the heterostructure. Alternatively, the tuning may be used to realize a varying composition level within the quaternary alloy layer. For instance, the Sc or Ga composition level may vary as a function of depth in the film. Respective composition levels appropriate or desirable for the adjacent layers in the heterostructure may accordingly be realized.

To further investigate the microstructure and impurity incorporation of the ScₓAl_{y}Ga_{1-x-y}N layers of the disclosed heterostructures, a ScₓAl_{y}Ga_{1-x-y}N/GaN multilayer stack sample was grown on GaN template using the conditions listed in Table I. Five ScₓAl_{y}Ga_{1-x-y}N layers separated by 80-nm-thick GaN layers were grown sequentially using the same growth conditions for the S1, S2, S3, S7, and S8 examples, respectively.

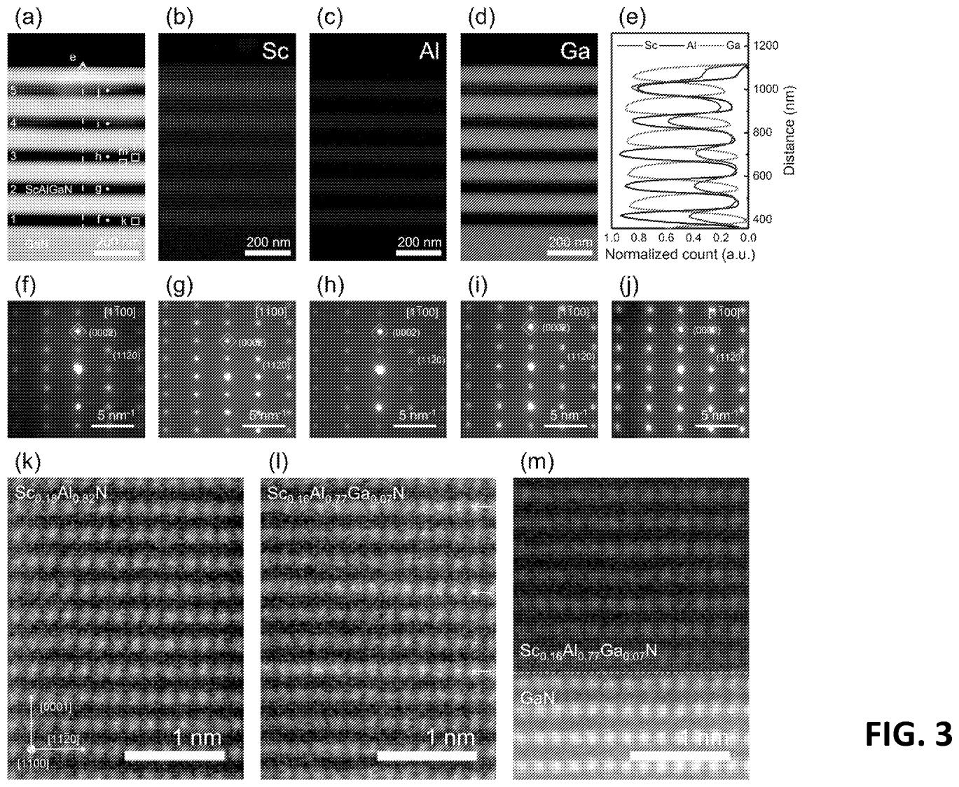

In Part A, FIG. 3 depicts a cross-sectional HAADF STEM image of a ScₓAl_{y}Ga_{1-x-y}N/GaN multilayer stack in accordance with one example. Parts B-D of FIG. 3 present corresponding EDS maps for the Sc, Al, and Ga element in the stack. Part E of FIG. 3 presents a EDS profile along the yellow dashed arrow indicated in the image of Part A. Parts F-J depict nanobeam diffraction (semi-convergence angle 0.6 mrad, camera length 410 mm) patterns acquired along the [11̅00] zone-axis from the yellow dots labeled in Part A, showing single-phase wurtzite structure for all ScₓAl_{y}Ga_{1-x-y}N layers. Green and red rhombuses indicate the diffraction spots from the (0002) and (112̅0) planes, respectively. Parts K-M are atomic resolved HAADF-STEM images of (k) Sc_{0.18}Al_{0.82}N, (I) Sc_{0.16}Al_{0.77}Ga_{0.07}N, and (m) Sc_{0.16}Al_{0.77}Ga_{0.07}N/GaN heterointerface regions captured from the yellow squares labeled in Part A. The yellow arrows in Part L indicate the Ga-rich layers, while the yellow dashed line in Part M shows the Sc_{0.16}Al_{0.77}Ga_{0.07}N/GaN heterointerface. Further details regarding the images and data presented in FIG. 3 are provided below.

Part A of FIG. 3 illustrates the cross-sectional HAADF-STEM image of a ScₓAl_{y}Ga_{1-x-y}N/GaN multilayer stack in accordance with one example. The corresponding EDS maps for Sc, Al, and Ga element are presented in parts B-D, respectively, confirming the uniform incorporation of Sc without any observable cluster formation. The EDS profile along the yellow dashed arrow in Part A is plotted in Part E. The incorporation of Ga into ScₓAl₁₋ₓN lattice is confirmed by the EDS line profile as the Ga minima increases for layers 2 to 5. The underlined values listed in Table I are the estimated atomic contents for Sc, Al, and Ga from EDS analysis by calibrating the first layer as Sc_{0.18}Al_{0.82}N. Nanobeam diffraction pattern data recorded from the yellow dots labeled in Part A are displayed in Parts F-J. Electron diffraction patterns confirm the multilayer stack consists of single-phase wurtzite structure, as the reciprocal lattice spacing ratio between the (0002) and (112̅0) plane reflections matches that for wurtzite crystal structure. This suggests that the incorporated Ga atoms and metal-rich conditions neither destroy the wurtzite structure nor introduce any intermetallic or rock-salt phases, which is in direct contrast with ScₓAl₁₋ₓN grown under metal-rich conditions.

To assess the tradeoff in micro-structural quality with incorporating Ga, atomic-resolved HAADF-STEM images were acquired around the Sc_{0.18}Al_{0.82}N and Sc_{0.16}Al_{0.77}Ga_{0.07}N regions. The regions are labeled as yellow rectangles in Part A of FIG. 3. The images are shown in parts K-M of FIG. 3. As shown in part K, Sc_{0.18}Al_{0.82}N has a uniform contrast, whereas some atomic layers with brighter contrast are observed in Sc_{0.16}Al_{0.77}Ga_{0.07}N, indicated as yellow arrows in part L. In the HAADF-STEM images, the brightest spots correspond to the heaviest atoms. Therefore, the periodical brighter contrast likely suggests the existence of an ordered alloy, i.e., Ga-poor ScₓAl_{y}Ga_{1-x-y}N layers is separated by a Ga-rich ScₓAl_{y}Ga_{1-x-y}N layer. Similar ordered alloys have been observed in InGaN and AlGaN, which were attributed to the strain induced nonlinear elements spatial distribution. Furthermore, shown in part M, an atomically sharp Sc_{0.16}Al_{0.77}Ga_{0.07}N/GaN interface is confirmed by the abrupt contrast change (indicated by the yellow dashed line). Compared with the blurry interface previously obtained at the ScₓAl₁₋ₓN/GaN interface, this atomic sharp ScₓAl_{y}Ga_{1-x-y}N/GaN interface is useful in reducing interface roughness scattering effect on the transport of charge carriers, which can significantly improve device performance.

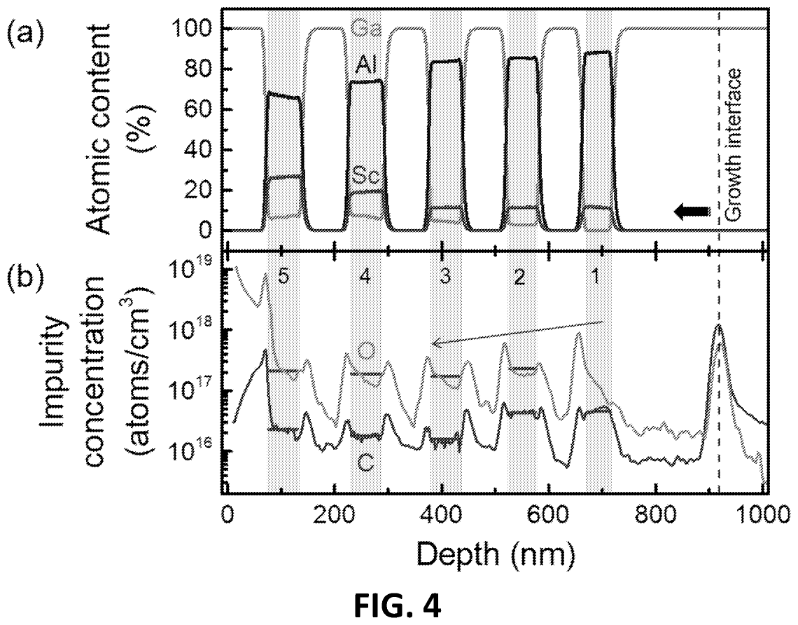

FIG. 4 depicts a SIMS profile of (Part A) main elements Sc, Al, and Ga, and (Part B) impurity elements O and C in a ScₓAl_{y}Ga_{1-x-y}N/GaN multilayer stack in accordance with one example. Gray (shaded) areas (1-5) represent ScₓAl_{y}Ga_{1-x-y}N and white (unshaded) areas point to GaN layers. A black dashed line and a black arrow indicate the growth interface and growth direction, respectively. The red solid lines in Part B depict the average impurity concentration in ScₓAl_{y}Ga_{1-x-y}N layers, while the red arrow indicates a decreasing trend of impurity density with increasing Ga flux. Further details regarding the data presented in FIG. 4 are provided below.

FIG. 4 shows the SIMS profile of the main elements (Sc, Al, and Ga) and impurity elements (O and C) recorded from the ScₓAl_{y}Ga_{1-x-y}N/GaN multilayer stack example described above. The Sc content was tuned well by adjusting the Sc and Al flux, as shown in Part A of FIG. 4. Meanwhile, the incorporation of Ga was confirmed by the existence of a Ga element signal in the ScₓAl_{y}Ga_{1-x-y}N layer (see, e.g., areas 2-5). The gradually increased Ga content agrees well with the STEM-EDS profile [see, e.g., part E of FIG. 3].

Shown in part B of FIG. 4, in the MBE grown GaN buffer layer, O and C concentrations are about 2×10¹⁶ and about 8×10¹⁵ cm⁻³, respectively. Due to the large oxygen affinity of Sc and Al, as well as the refractory nature of Sc₂O₃ and Al₂O₃, Sc Al_{y}Ga_{1-x-y}N layers (areas 1-5) exhibit higher O and C concentrations than GaN layers. The spikes located at the ScₓAl_{y}Ga_{1-x-y}N/GaN heterointerfaces in the O and C profiles are likely due to the impurity incorporation during the growth interruption of each layer. The average O and C concentrations in ScₓAl_{y}Ga_{1-x-y}N layers are depicted as red solid lines in part B. Interestingly, O concentration of ScₓAl_{y}Ga_{1-x-y}N shows a slight reduction with increasing Ga flux indicated by red arrow in Part B (areas 1-3), and it has little change with increasing Sc content [Part B, areas 3-5)]. This phenomenon is in contrast to previous reports on ScₓAl₁₋ₓN and ScₓGa₁₋ₓN, in which the impurity concentration has a clear increasing trend with the increase of Sc content. Therefore, the incorporation of Ga is beneficial to suppressing impurity incorporation during the growth of ScₓAl₁₋ₓN. The average O concentration in all ScₓAl_{y}Ga_{1-x-y}N layers are below about 3×10¹⁷ cm⁻³, which is three to four orders of magnitude lower than that of ScₓAl₁₋ₓN grown on AlN templates with similar Sc contents reported in a previous study. The incorporation of C impurity shows a similar trend with an average concentration below about 5×10¹⁶ cm⁻³ for all ScₓAl_{y}Ga_{1-x-y}N layers. This improvement suggests an efficient approach to suppress the impurity incorporation in Sc-III-N alloys, facilitating applications in electronic, optoelectronic and other devices.

One or more aspects of the disclosed methods may lead to the low concentration levels of impurities in the quaternary or higher order alloy layers of the disclosed heterostructures. For instance, the disclosed methods may include a growth procedure in which a template or other III-nitride layer and the quaternary alloy layer are grown in the same growth chamber. The layers of the heterostructure may thus be grown without removal of the substrate from the growth chamber. Exposure to the ambient environment and/or other sources of impurities may accordingly be limited or better controlled.

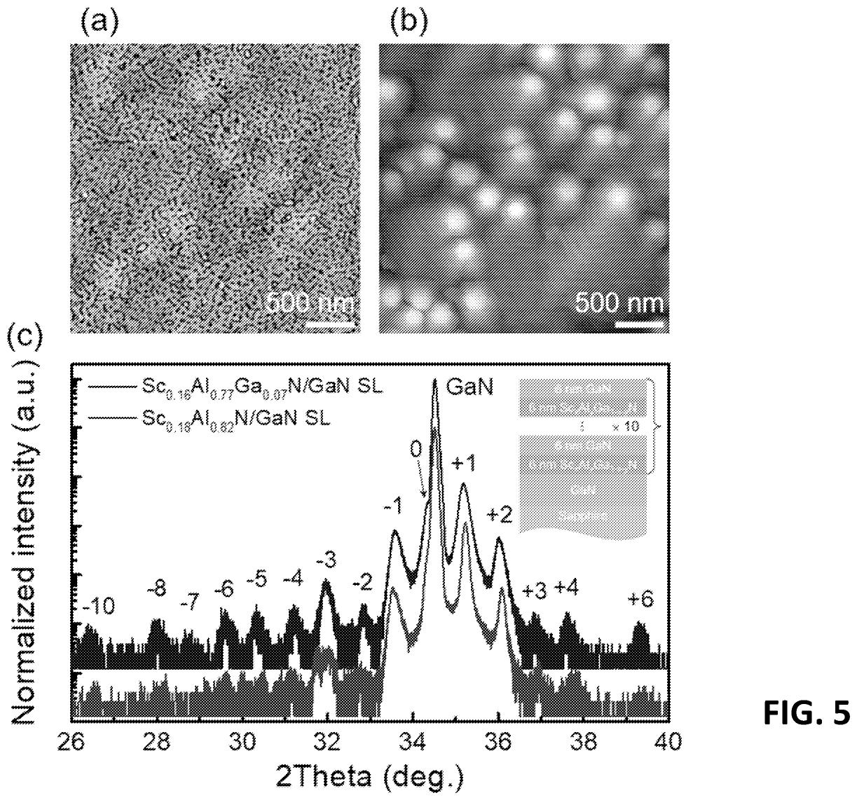

FIG. 5 depicts 3×3 μm² AFM images of superlattice (SL) heterostructures in accordance with two examples. Part A shows a Sc_{0.18}Al_{0.82}N/GaN SL heterostructure. Part B shows a Sc_{0.16}Al_{0.77}Ga_{0.07}N/GaN SL heterostructure. The height color scale range is 10 nm. Part C depicts XRD 2θ-ω scans of (0002) plane for the Sc_{0.18}Al_{0.82}N/GaN and Sc_{0.16}Al_{0.77}Ga_{0.07}N/GaN SL heterostructures. Inset in the graphical plot of part C is a schematic view of the ScₓAl_{y}Ga_{1-x-y}N/GaN SL heterostructure. Further details regarding the images and data presented in FIG. 5 are provided below.

The improvements in surface morphology and crystal quality by incorporating Ga into ScₓAl₁₋ₓN enables the design and growth of Sc-III-N-based quantum structures. Two examples of ScₓAl_{y}Ga_{1-x-y}N/GaN superlattice (SL) structures were grown to confirm this. The examples are depicted in FIG. 5. During the growth of the ScₓAl_{y}Ga_{1-x-y}N layers, the same growth conditions used for samples S1 and S3 were used. Therefore, the ScₓAl_{y}Ga_{1-x-y}N layers in these two SL heterostructures may have the same atomic percentage as samples S1 and S3.

Parts A and B of FIG. 5 depict the surface morphology of 10 periods of alternating layers of Sc_{0.18}Al_{0.82}N and GaN, and Sc_{0.16}Al_{0.77}Ga_{0.07}N and GaN, respectively. Due to the N-rich growth conditions in the ScAlN heterostructure, high density of pits formed on the surface of Sc_{0.18}Al_{0.82}N/GaN SL (RMS=1.24 nm). In contrast, a smooth surface with clear spiral atomic steps was observed for Sc_{0.16}Al_{0.77}Ga_{0.07}N/GaN SL (RMS=1.04 nm) grown under slightly Ga-rich conditions. Consequently, a XRD 2θ-ω scan of the symmetric (0002) plane shows more than fourteen satellite peaks for Sc_{0.16}Al_{0.77}Ga_{0.07}N/GaN SL [Part C, FIG. 5, blue curve], indicating a clear periodicity with sharp interfaces. For comparison, the satellite peaks of Sc_{0.18}Al_{0.82}N/GaN SL start to attenuate noticeably by the fourth order [Part C, FIG. 5, red curve]. The deduced thicknesses of the superlattices (d_{SL}) are 11.6 and 11.3 nm for Sc_{0.16}Al_{0.77}Ga_{0.07}N/GaN and Sc_{0.18}Al_{0.82}N/GaN SLs, respectively, which are in good agreement with the designed structures [Part C, FIG. 5, inset].

Owing to the large spontaneous polarization nature, ScₓAl₁₋ₓN is a promising barrier for GaN-based HEMT structures. Both metal-polar and N-polar GaN HEMTs using ScₓAl₁₋ₓN as a barrier layer have been demonstrated recently.

Two examples of HEMT structures or devices were grown using a ternary alloy Sc_{0.18}Al_{0.82}N and a quaternary alloy Sc_{0.16}Al_{0.77}Ga_{0.07}N as a barrier to compare the tradeoff in sheet electron concentration with respect to carrier mobility as Ga is introduced. A 100-nm-thick unintentionally doped GaN buffer layer was first deposited on commercial Fe-doped semi-insulating GaN/sapphire template, followed by a 2-nm-thick AlN spacer layer. The AlN spacer layer may thus be grown in the same growth chamber as the subsequent layers of the heterostructure. Subsequently, nominal 10-nm-thick Sc_{0.18}Al_{0.82}N or 12-nm-thick Sc_{0.16}Al_{0.77}Ga_{0.07}N was grown as a barrier layer, followed by 2 nm GaN capping layer. The Fe-doped semi-insulating GaN templates were used to avoid parallel conduction channel formation, while the AlN insert or spacer layer and GaN capping layer were used to reduce the interface roughness scattering and to suppress the surface oxidation, respectively. In this structure, two-dimensional electron gas (2DEG) is confined near the interface between the GaN buffer layer and AlN/Sc Al_{y}Ga_{1-x-y}N barrier layer. The barriers were grown using the same conditions as that applied for samples S1 and S3. Van der Pauw Hall measurements were used to determine the 2DEG density (nₛ) and mobility (μ) at room temperature, which are listed in Table II. A sheet charge density of 4.2×10¹³ cm⁻² with an improved electron mobility of about 869 cm²/V-s and a corresponding sheet resistance of about 171 Ω/sq was achieved by replacing the Sc_{0.18}Al_{0.82}N barrier with Sc_{0.16}Al_{0.77}Ga_{0.07}N. The slightly higher electron concentration for the HEMT structure using Sc_{0.16}Al_{0.77}Ga_{0.07}N as the barrier is likely due to the larger barrier thickness.

TABLE II
Electrical properties of GaN HEMTs using Sc_{0.18}Al_{0.82}N
and Sc_{0.16}Al_{0.77}Ga_{0.07}N as barrier.

| | Thickness | nₛ | μ | Rₛ |
|---|---|---|---|---|
| Barrier | (nm) | (cm⁻²) | (cm²/V · s) | (Ω/sq) |
| Sc_{0.18}Al_{0.82}N | 10 | 3.6 × 10¹³ | 744 | 233 |
| Sc_{0.16}Al_{0.77}Ga_{0.07}N | 12 | 4.2 × 10¹³ | 869 | 171 |

In some other cases, the quaternary or higher order III-nitride semiconductor layer involves alloying ScAlN with In, forming ScₓAl_{y}In_{1-x-y}N films or other layers. All of the utility, features, and other characteristics of the above-described ScₓAl_{y}Ga_{1-x-y}N may also be provided or achieved with ScₓAl_{y}In_{1-x-y}N. For example, ScₓAl_{y}In_{1-x-y}N also provides a useful approach for achieving high quality ScAlN-based semiconductor layers that was not previously possible, and further offers additional dimensions for bandgap, polarization, interface, strain, and quantum engineering. The resulting quaternary alloy ScₓAl_{y}In_{1-x-y}N exhibits single-phase wurtzite structure, an atomically smooth surface, high crystal quality, a sharp interface, and low impurity concentration.

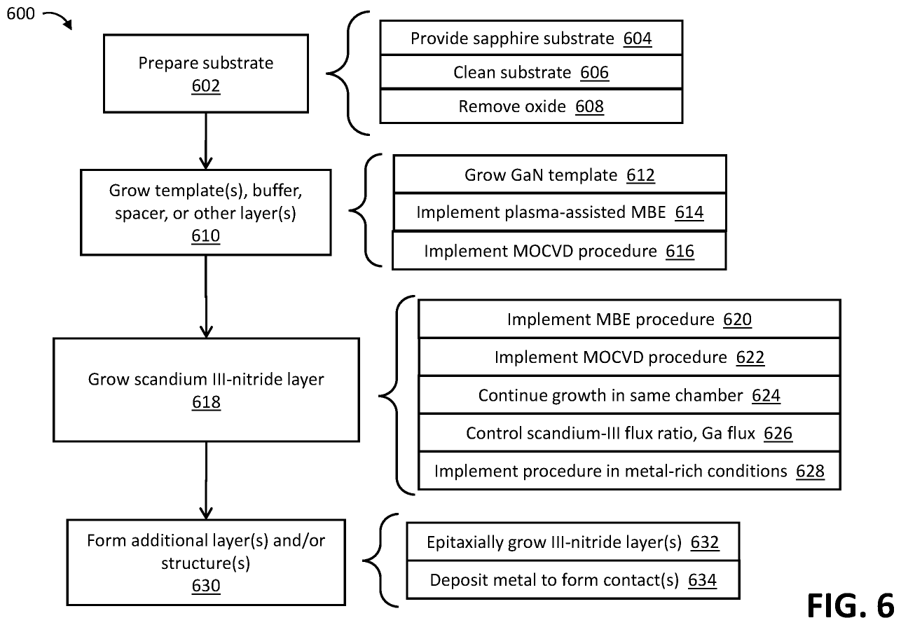

FIG. 6 depicts a method 600 of fabricating a heterostructure having a quaternary or higher order III-nitride alloy layer in accordance with one example. As described herein, the method 600 may be configured such that the quaternary or higher order III-nitride alloy layer includes a group IIIB element, such as scandium. The heterostructure may form a device, or a part of a device, such as a HEMT device. The method 600 may be used to fabricate the examples of ScₓAl_{y}Ga_{1-x-y}N or ScₓAl_{y}In_{1-x-y}N films and layers described herein.

The method 600 may begin with an act 602 in which a substrate is prepared and/or otherwise provided. In some cases, the act 602 includes providing a sapphire substrate in an act 604. Alternative or additional materials may be used, including, for instance, silicon, bulk GaN, bulk AlN, or other semiconductor material. Still other materials may be used, including, for instance, silicon carbide. The substrate may be cleaned in an act 606. In some cases, a native or other oxide layer may be removed from a substrate surface in an act 608. Additional or alternative processing may be implemented in other cases, including, for instance, doping or deposition procedures. The substrate thus may or may not have a uniform composition. The substrate may be a uniform or composite structure.

In an act 610, one or more semiconductor growth templates, buffer, spacer, or other layers are epitaxially grown. The semiconductor layer(s) are thus formed on, or otherwise supported by, the substrate. The semiconductor layer(s) may or may not be in contact with the substrate. In some cases, the semiconductor layer(s) are composed of, or otherwise include, GaN, but other III-nitride semiconductor materials may be used, including, for instance, AlN, AlGaN, AlInN, and InGaN. In the example of FIG. 6, a GaN layer is grown in an act 612. In such cases, the semiconductor layer may act as a template for subsequent growth of one or more semiconductor layers. In some cases, the GaN layer is Ga-polar, and may be grown in slightly Ga-rich conditions. In other cases, the method 600 may be applied to N-polar GaN.

The act 612 may thus be implemented before (e.g., in preparation for) implementing an epitaxial growth procedure in which a quaternary or higher order III-nitride alloy layer is formed. The quaternary or higher order III-nitride alloy layer may thus be formed on the semiconductor layer. The semiconductor layer may be configured or used as a growth template for the quaternary or higher order III-nitride alloy layer and/or other elements of the heterostructure. In some cases, the act 612 may include growing the semiconductor layer in an epitaxial growth chamber in which the epitaxial growth procedure for the quaternary or higher order III-nitride alloy layer is implemented. As a result, the substrate may remain within, e.g., is not removed from, the epitaxial growth chamber between forming the semiconductor layer and implementing the epitaxial growth procedure for growing the quaternary or higher order III-nitride alloy layer.

The act 610 may include an act 614 in which the semiconductor layer is grown via implementation of a plasma-assisted MBE procedure. Alternative or additional procedures may be used. For instance, the semiconductor layer may be grown in an act 616 via implementation of a MOCVD procedure.

The GaN template or other semiconductor layer(s) grown in the act 610 may be grown directly on the substrate. For instance, the GaN template or other semiconductor layer is grown without an AlN buffer layer. This is in contrast to previous techniques in which the GaN template or other semiconductor layer was grown on an AlN buffer, which results in a metal-polar GaN layer. Without the AlN buffer layer, the GaN template or other semiconductor layer may be grown in a manner that results N-polarity.

After growing the semiconductor layer in the act 610, another semiconductor layer of the heterostructure is grown in an act 618 such that the semiconductor layer is supported by the semiconductor layer grown in the act 610. The semiconductor layer grown in the act 618 is composed of, or otherwise includes, a quaternary or higher order III-nitride alloy that includes a group IIIB element, such as scandium. For instance, the quaternary or higher order III-nitride alloy may be ScAlGaN, ScGaInN, ScAlInN, and their higher order alloys (e.g., a pentanary III-nitride alloy, such as ScAlGaInN). In some cases, one or both of the semiconductor layers formed in the acts 610 and 618 are metal-polar. In other cases, the method 600 may be applied for N-polar structures. The growth conditions may be set such that the semiconductor layers may be lattice matched or mismatched, as described herein.

The act 618 may include an act 620 in which the quaternary or higher order III-nitride alloy layer is grown via implementation of an MBE procedure. Alternatively, a MOCVD procedure is implemented in an act 622. In either case, the growth may be continued in an act 624 in which in the same chamber used in the act 610 is used to grow the quaternary or higher order III-nitride alloy layer.

The growth conditions may be controlled to establish a scandium (or other group IIIB element) content of the quaternary or higher order III-nitride alloy layer. For instance, the scandium-gallium (or other Group III element) flux ratio and/or the flux ratio may be controlled in an act 626. In some cases, the scandium-III flux ratio is controlled such that a scandium content of the scandium III-nitride semiconductor material falls in a range from about 0.10 to about 0.50. However, the scandium (or other group IIIB element) content may fall outside of the range in other cases. The Ga, Al, or other Group III element composition may fall in a range of about 0 to about 0.30.

The act 626 may alternatively or additionally include controlling the Ga flux. The Ga flux may be controlled separately or independently of the Sc-III ratio.

The control in the act 626 may include or involve adjusting the of the flux ratios and other fluxes while the layer is growing. The composition of the layer may thus change as a function of depth.

The quaternary or higher order III-nitride alloy layer may be grown at a growth temperature falling in a range from about 400 degrees C. to about 900 degrees C. For example, the growth temperature may be about 700 degrees C. Other growth temperatures may be used in other cases, including, for instance, temperatures below 600 degrees C.

The act 618 may also include an act 628 in which the quaternary or higher order III-nitride alloy layer is implemented either partially or entirely in a metal-rich environment, e.g., under metal-rich conditions such as Ga-rich conditions. One or more of the other semiconductor layers of the heterostructure may also be grown under metal-rich conditions. Alternatively, one or more of the other semiconductor layers may be grown under nitrogen-rich conditions.

The method 600 may include an act 630 in which one or more additional layers or other structures are formed. In some cases, the act 630 includes growing one or more III-nitride layers in an act 632. For example, a channel layer and/or cap layer of a HEMT device may be grown.

The act 630 may also include an act 634 in which one or more metal layers are deposited and patterned to form one or more contacts or electrodes. For example, metal may be deposited to form source, drain, and gate electrodes of an HEMT device.

The method 600 may include fewer, alternative, or additional acts. For example, the method 600 may include the implementation of one or more doping procedures for one or more of the semiconductor layers described herein. Such doping may be useful in connection with charge carrier confinement and/or other purposes. The method 600 may also include any number of additional acts directed to the growth or other formation of additional semiconductor layers, such as cap layers.

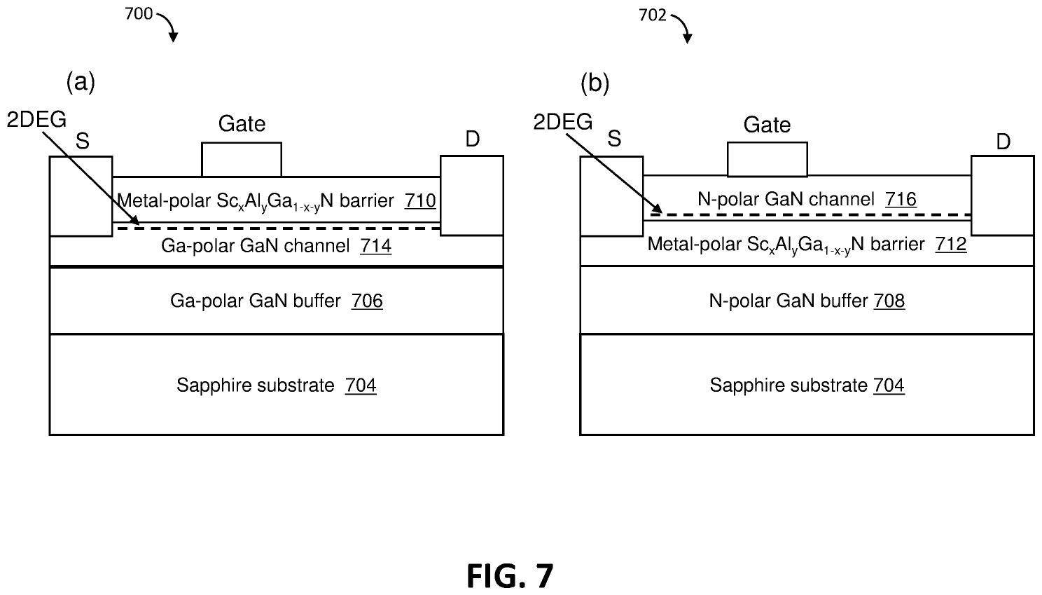

FIG. 7 depicts devices 700, 702 having a quaternary or higher order III-nitride alloy layer in accordance with two examples. The devices 700, 702 may be fabricated via the method 600 of FIG. 6 and/or another method. In these two examples, the device 700 is configured as metal-polar HEMT device (Part A), and the device 702 is configured as a nitrogen-polar HEMT device (Part B). In other cases, the device is configured as a non-electronic device.

Each device 700, 702 includes a substrate 704 and a semiconductor heterostructure supported by the substrate 704. The substrate 704 may be composed of, or otherwise include, sapphire, but alternative or additional materials may be used, including for instance, SiC. In the examples of FIG. 7, the heterostructure is in contact with the substrate 704. In other cases, one or more layers are disposed between the substrate 704 and the heterostructure.

Each device 700, 702 includes a buffer or other semiconductor layer of the heterostructure. The device 700 includes a Ga-polar buffer layer 706. The device 702 includes a N-polar buffer layer 708. Each buffer layer 706, 708 is supported by the substrate 704. In the examples of FIG. 7, each buffer layer 706, 708 is in contact with the substrate 704. Each buffer layer 706, 708 is composed of, or otherwise includes, a first III-nitride semiconductor material. In some cases, the first III-nitride semiconductor material is GaN, but other III-nitride materials may be used, including, for instance, AlN and alloys of AlN and GaN. Each buffer layer 706, 708 may be doped, unintentionally doped, or un-doped.

In some cases, one or both of the devices 700, 702 further includes a spacer layer. The spacer layer may be in contact with the buffer layer 706, 708. The spacer layer may be composed of, or otherwise include, a III-nitride semiconductor material, such as AlN, but other materials may be used.

Each device 700, 702 includes a barrier or other semiconductor layer of the heterostructure. The device 700 includes a barrier layer 710. The device 702 includes a barrier layer 712. Each barrier layer 710, 712 is supported by the respective buffer layer of the heterostructure. In the device 702, the barrier layer 712 is in contact with the buffer layer 708. In the device 700, the barrier layer 710 is spaced from the buffer layer 706. Each barrier layer 710, 712 is composed of, or otherwise includes, a quaternary or higher order III-nitride alloy. The quaternary or higher order III-nitride alloy may differ from the first III-nitride semiconductor material. The quaternary or higher order III-nitride alloy may include scandium, such as ScₓAl_{y}Ga_{1-x-y}N, as described herein. The scandium composition may fall within a range of about 0.10 to about 0.50. Other group IIIB elements may be used.

The buffer, barrier, and other layers of the devices 700, 702 may be lattice matched or lattice mis-matched.

In the HEMT examples of FIG. 7, each device 700, 702 also includes a channel layer. The device 700 includes a channel layer 714. The device 702 includes a channel layer 716. In the metal-polar HEMT structure of the device 700 (Part A), the channel layer 714 supports the barrier layer 710. In nitrogen-polar HEMT structure of the device 702 (Part B), the channel layer 716 is supported by the barrier layer 712. The channel layers 714, 716 thus may be in contact with a barrier layer. In other cases, one or more semiconductor layers may be disposed between the channel and barrier layers. Each channel layer 714, 716 is composed of, or otherwise includes, a compound semiconductor material, such as a III-nitride semiconductor material, e.g., GaN, AlGaN, InGaN, or InN.

In some cases, the barrier layer of the devices described herein has a terraced surface distal to the buffer layer (or other lower layer) and proximate to the channel layer (or other higher layer). In the examples of FIG. 7, the upper or top surface of the barrier layer 710, 712 is terraced. The terraced surface may include any number of atomic steps. The atomic steps may be indicative of growth on a monolayer-by-monolayer basis. The presence of atomic steps may result from the growth of the quaternary or higher order III-nitride alloy in a metal-rich environment. In contrast, growth of the quaternary or higher order III-nitride alloy in a nitrogen-rich environment would not result in the presence of atomic steps along the upper surface.

In some cases, one or more of the above-described layers are metal-polar. In other cases, one or more of the layers other than the quaternary III-nitride alloy layer are nitrogen-polar.

The heterostructures of the devices 700, 702 may include one or more further semiconductor layers. For instance, the heterostructure may include a semiconductor layer disposed between the buffer and barrier layers. The further semiconductor layer may be composed of, or otherwise include, a third III-nitride semiconductor material (e.g., AlN) differing from the first III-nitride semiconductor material. The further semiconductor layer may be metal-polar as well, insofar as the lattice polarity of the layers of the heterostructure may follow the polarity of the initial buffer layer.

Described above are examples of the growth of single-phase wurtzite quaternary or higher order alloys, such as ScₓAl_{y}Ga_{1-x-y}N, through introducing Ga during the epitaxy of ScₓAl₁₋ₓN. An atomically smooth surface, high crystal quality, a sharp interface, and significantly reduced impurity incorporation, which are previously unattainable for ScₓAl₁₋ₓN, were achieved for ScₓAl_{y}Ga_{1-x-y}N with varying Sc contents (e.g., x of about 0.16-26). The improved morphology and crystal quality are further evidenced by the clear periodicity and sharp interface of Sc_{0.16}Al_{0.77}Ga_{0.07}N/GaN SL, as well as the enhanced electrical properties of GaN HEMTs using Sc_{0.16}Al_{0.77}Ga_{0.07}N as barrier. The epitaxial growth of quaternary alloy ScₓAl_{y}Ga_{1-x-y}N provides a viable path to improve the material quality of the state-of-the-art ferroelectric ScₓAl₁₋ₓN, and also offers promising opportunities and design options for bandgap, polarization, and strain engineering as well as ferroelectricity tuning of Sc-III-N material devices and systems, with applications in photonic, optoelectronic, electronic, ferroelectric and other devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method of fabricating a heterostructure, the method comprising:
growing epitaxially, in a growth chamber, a first semiconductor layer of the heterostructure, the first semiconductor layer comprising a III-nitride semiconductor material, the first semiconductor layer being supported by a substrate; and
after growing the first semiconductor layer, growing epitaxially, in the growth chamber, a second semiconductor layer of the heterostructure such that the second semiconductor layer is supported by the first semiconductor layer, the second semiconductor layer comprising a quaternary or higher order III-nitride alloy,
wherein the quaternary or higher order III-nitride alloy comprises a group IIIB element.

2. The method of claim 1, wherein growing epitaxially the second semiconductor layer is implemented in a metal-rich environment.

3. The method of claim 1, wherein growing epitaxially the second semiconductor layer is implemented in a gallium-rich or indium-rich environment.

4. The method of claim 1, wherein growing the second semiconductor layer is implemented without removal of the substrate from the growth chamber after growth of the first semiconductor layer.

5. The method of claim 1, wherein growing epitaxially the second semiconductor layer comprises adjusting a IIIB element/metal flux ratio during epitaxial growth of the second semiconductor layer.

6. The method of claim 5, wherein the IIIB element/metal flux ratio is a scandium/aluminum flux ratio.

7. The method of claim 1, wherein growing epitaxially the second semiconductor layer is implemented with a flux ratio such that a composition of the group IIIB element falls in a range from about 0.10 to about 0.50.

8. The method of claim 1, wherein the group IIIB element is a lanthanide element.

9. A method of fabricating a heterostructure, the method comprising:
growing epitaxially a first semiconductor layer of the heterostructure, the first semiconductor layer comprising a III-nitride semiconductor material, the first semiconductor layer being supported by a substrate; and
after growing the first semiconductor layer, growing epitaxially a second semiconductor layer of the heterostructure such that the second semiconductor layer is supported by the first semiconductor layer, the second semiconductor layer comprising a quaternary or higher order III-nitride alloy,
wherein:
the quaternary or higher order III-nitride alloy comprises a group IIIB element; and
growing the second semiconductor layer is implemented at least partially in a metal-rich environment.

10. The method of claim 9, wherein the metal-rich environment is a gallium-rich or indium-rich environment.

11. The method of claim 9, wherein growing the first semiconductor layer and growing the second semiconductor layer are implemented without removal of the substrate from a growth chamber in which the first and second semiconductor layers are grown.

12. The method of claim 9, wherein growing epitaxially the second semiconductor layer comprises adjusting a IIIB element/metal flux ratio during epitaxial growth of the second semiconductor layer.

13. The method of claim 12, wherein the IIIB element/metal flux ratio is a scandium/aluminum flux ratio.

14. A device comprising:
a substrate; and
a semiconductor heterostructure supported by the substrate, the semiconductor heterostructure comprising:
a first semiconductor layer supported by the substrate and comprising a III-nitride semiconductor material; and
a second semiconductor layer supported by the first semiconductor layer and comprising a quaternary or higher order III-nitride alloy, the quaternary or higher order III-nitride alloy comprising a group IIIB element;
wherein the second semiconductor layer has a terraced surface distal to the first semiconductor layer.

15. The device of claim 14, wherein the terraced surface comprises a plurality of atomic steps.

16. The device of claim 14, wherein a composition of the group IIIB element falls in a range from about 0.10 to about 0.50.

17. The device of claim 14, wherein the second semiconductor layer is in contact with the first semiconductor layer.

18. The device of claim 14, further comprising a third semiconductor layer disposed between the first and second semiconductor layers, wherein the third semiconductor layer comprises a further III-nitride semiconductor material differing from the III-nitride semiconductor material of the first semiconductor layer.

19. The device of claim 14, wherein the first and second semiconductor layers are lattice matched.

20. The device of claim 14, wherein the first and second semiconductor layers are lattice mismatched.

21. The device of claim 14, wherein the second semiconductor layer is configured as a dielectric layer.

22. A device comprising:
a substrate; and
a semiconductor heterostructure supported by the substrate, the semiconductor heterostructure comprising:
a first semiconductor layer supported by the substrate and comprising a III-nitride semiconductor material; and
a second semiconductor layer supported by the first semiconductor layer and comprising a quaternary or higher order III-nitride alloy, the quaternary or higher order III-nitride alloy comprising a group IIIB element;
wherein a composition of the group IIIB element falls in a range from about 0.10 to about 0.50.

23. A transistor device comprising:
a substrate;
a buffer layer supported by the substrate and comprising a III-nitride semiconductor material; and
a barrier layer supported by the buffer layer and comprising a quaternary or higher order III-nitride alloy, the quaternary or higher order III-nitride alloy comprising a group IIIB element;
wherein the barrier layer has a terraced surface distal to the buffer layer.

24. The transistor device of claim 23, further comprising a channel layer supported by the barrier layer and comprising a compound semiconductor material, wherein the terraced surface is proximate to the channel layer.

25. The transistor device of claim 23, further comprising a channel layer disposed between the buffer layer and the barrier layer and comprising a compound semiconductor material, wherein the terraced surface is distal to the channel layer.

26. The transistor device of claim 23, wherein the compound semiconductor material and the quaternary or higher order III-nitride alloy are lattice mismatched.

27. The transistor device of claim 23, wherein the compound semiconductor material and the quaternary or higher order III-nitride alloy are lattice matched.

28. The transistor device of claim 23, wherein the III-nitride semiconductor material and the quaternary or higher order III-nitride alloy are lattice mismatched.

29. The transistor device of claim 23, further comprising a further semiconductor layer disposed between the buffer and barrier layers, wherein the further semiconductor layer comprises a further III-nitride semiconductor material differing from the III-nitride semiconductor material of the first semiconductor layer.
